(19) United States
(12) Patent Application Publication
(10) Pub. No.: US 2006/0228888 A1
(43) Pub. Date: Oct. 12, 2006

(54) Atomic layer deposition of high k metal silicates

(76) Inventors: Sang-In Lee, Cupertino, CA (US); Yoshihide Senzaki, Aptos, CA (US); Sang-Kyoo Lee, Seoul (KR)

Correspondence Address: DORSEY & WHITNEY LLP, 555 CALIFORNIA STREET, SUITE 1000, SUITE 1000, SAN FRANCISCO, CA, 94104, US

(21) Appl. No.: 10/525,122

(22) PCT Filed: Aug. 18, 2003
(86) PCT No.: PCT/US03/25739

§ 371 Date: Mar. 20, 2006

Related U.S. Application Data
(60) Provisional application No. 60/404,371, filed on Aug. 18, 2002.

(51) Int. Cl. H01L 21/44; H01L 51/40

(52) U.S. Cl. 438/681; 438/99

(57) ABSTRACT

The present invention relates to the atomic layer deposition (“ALD”) of high k dielectric layers of metal silicates, including hafnium silicate. More particularly, the present invention relates to the ALD formation of metal silicates using metal organic precursors, silicon organic precursors and ozone. Preferably, the metal organic precursor is a metal alkyl amide and the silicon organic precursor is a silicon alkyl amide.

### CROSS-REFERENCE TO RELATED APPLICATIONS

This application is related to, and claims priority to, U.S. Provisional Patent Application No. 60/404,371, entitled Atomic Layer Deposition of Metal Silicates for High-k Gate and Capacitor Dielectrics, filed Aug. 18, 2002, the entire disclosure of which is hereby incorporated by reference. This application is also related to U.S. Provisional Patent Application No. 60/396,723, entitled Atomic Layer Deposition of High-k Dielectric Films, filed Jul. 19, 2002 which is hereby incorporated by reference.

### FIELD OF THE INVENTION

The present invention relates to the atomic layer deposition (“ALD”) of high k dielectric films of metal silicate, such as hafnium silicate. More particularly, the present invention relates to the ALD formation of metal silicate from a metal organic precursor, a silicon organic precursor and ozone.

### BACKGROUND OF THE INVENTION

The speed and functionality of computers doubles every year, facilitated in large part by the shrinking dimensions of integrated circuits. Currently, the smallest dimension in modern circuits is the thickness of the gate insulator, which separates the controlling electrode (“gate electrode”) from the controlled current in the silicon. Traditionally, the gate insulator has been made from silicon dioxide (SiO₂) and/or silicon nitride (SiN). Such insulators are now as thin as 20 Å. However, conventional gate dielectrics suffer from leakage and reliability deficiencies as the thickness decreases below 20 Å.

Accordingly, efforts are underway to find alternative insulators. To date, efforts have focused largely on high dielectric constant (high “k”) materials. As used herein, a material is “high k” if its dielectric constant “k” is higher than the dielectric constant of silicon oxide (k=3.9). The need for high k gate dielectrics with complementary field effect transistor integration is identified in the International Technology Roadmap for Semiconductors. High k dielectrics that have been investigated include metal silicates.

In addition, prior art deposition techniques, such as chemical vapor deposition (CVD), are increasingly unable to meet the requirements of advanced thin films. While CVD processes can be tailored to provide conformal films with improved step coverage, CVD processes often require high processing temperatures, result in the incorporation of high impurity concentrations, and have poor precursor or reactant utilization efficiency. For instance, one of the obstacles of making high k gate dielectrics is the formation of interfacial silicon oxide layers during CVD processes. Another obstacle is the limitation of prior art CVD processes in depositing ultra thin films for high k gate dielectrics on a silicon substrate.

Accordingly, efforts are underway to develop improved methods for depositing materials in pure form with uniform stoichiometry, thickness, conformal coverage, abrupt interface, smooth surface, and reduced grain boundaries, cracks and pinholes. ALD is the latest method to be developed. In ALD, precursors and co-reactants are brought to the surface of a growing film separately, through alternating pulses and purges, to generate a single mono-layer of film growth per pulse cycle. Layer thickness is controlled by the total number of pulse cycles. ALD has several advantages to CVD. ALD can be performed at comparatively lower temperatures which is compatible with the industry's trend toward lower temperatures, and can produce conformal thin film layers. More advantageously, ALD can control film thickness on an atomic scale, and can be used to “nano-engineer” complex thin films. Accordingly, further developments in ALD are highly desirable.

The use of metal alkyl amides as metal organic precursors in ALD is known. For example, the ALD formation of hafnium oxide using hafnium tetrakis (dimethyl amide) (“Hf-TDMA”) and hafnium tetrakis (ethyl methyl amide) (“Hf-TEMA”) has been reported. See Vapor Deposition Of Metal Oxides And Silicates: Possible Gate Insulators For Future Microelectronics, R. Gordon et al., Chem. Mater., 2001, pp. 2463-2464 and Atomic Layer Deposition of Hafnium Dioxide Films From Hafnium Tetrakis(ethylmethylamide) And Water, K. Kukli et al., Chem. Vap. Deposition, 2002, Vol. 8, No. 5, pp. 199-204, respectively. However, these references do not use metal alkyl amides to form metal silicates. Furthermore, these references do not describe the preferential use of ozone as an oxidant.

Ozone is a known oxidizer. For example, ozone is one of many suitable oxidizers reported in an ALD process to make zirconium oxide from zirconium tetra-t-butoxide. See U.S. Pat. No. 6,465,371. However, oxygen and/or steam tend to be preferred oxidants in the ALD formation of metal oxides. See, e.g., Atomic Layer Deposition of Hafnium Dioxide Films from Hafnium Tetrakis(ethylmethylamide) And Water.

### SUMMARY OF THE INVENTION

The invention provides ALD processes for forming high k metal silicates, including hafnium silicate, to replace silicon dioxide in gate and/or capacitor dielectric applications. The method entails the following steps: first, concurrently or consecutively pulsing a metal organic precursor and a silicon organic precursor into a reaction chamber containing a substrate; second, purging the reaction chamber; third, pulsing ozone into the reaction chamber; and fourth, purging the reaction chamber. This pulse cycle is repeated until a metal silicate film of target thickness is achieved.

The metal organic precursor can any metal donating organic material. Preferred metal organic precursors include metal alkyls, metal alkoxides and metal alkyl amides. Preferably, the metal organic precursor is a metal alkyl amide. Even more preferably, the metal organic precursor is a metal alkyl amide containing ethylmethyl amide ligands. Such precursors exhibit reduced carbon contamination in the resultant metal silicate film.

The silicon organic precursor can be any silicon donating organic material. Preferred silicon organic precursors include alkyl silanes, silicon alkoxides, siloxanes, silazanes, and silicon alkyl amides. Preferably, however, the silicon organic precursor is a silicon alkyl amide. Even more preferably, the silicon organic precursor is silicon tetrakis (ethyl methyl amide). Once again, these precursors exhibit reduced carbon contamination.

By using ozone in the ALD process, as opposed to conventional oxidants such as steam, the fixed and trapped charges in the resultant metal silicate film are significantly reduced. In addition, by using ozone in the ALD process, as opposed to conventional oxidants such as oxygen gas, the required operating temperatures for the ALD process are significantly reduced.

The high k metal silicate films produced in accordance with the invention are useful as dielectrics in gates and capacitors. When used as a gate dielectric, the high k dielectric films are formed on a substrate, generally a silicon wafer, between one or more n or p doped channels. Then an electrode, such as a polycrystalline silicon electrode, is formed over the dielectric to complete the gate. When used as a capacitor dielectric, the high k dielectric films are formed between two conductive plates.

### BRIEF DESCRIPTION OF THE DRAWINGS

The invention will be described in detail with reference to the following figures, wherein:

FIG. 1 is a flow diagram that outlines the ALD pulse cycle of the instant invention; and

FIG. 2 illustrates the use of a high k dielectric film produced in accordance with the invention in a gate.

### DETAILED DESCRIPTION OF THE PREFERRED EMBODIMENTS

The invention provides ALD processes for forming high k metal silicates to replace silicon dioxide in gate and/or capacitor dielectric applications. A preferred metal silicate formed according to the process is hafnium silicate. Hafnium silicate exhibits superior thermal stability and, thereby, results in less interfacial silicon dioxide growth, compared to other silicates.

Prior to starting the pulse cycle, a substrate, generally a silicon wafer, is placed into a reaction chamber, often through a valve located at one end of the chamber. Preferably, the silicon wafer has been cleaned with hydrogen fluoride to remove native silicon dioxide.

The substrate sits on a heatable wafer holder that supports and heats the substrate to the desired reaction temperature. Once the substrate is properly positioned, the pulse cycle can begin.

Generally, prior to the first pulse in the pulse cycle, the wafer is heated to a temperature ranging from about 100° C. to about 500° C., and preferably ranging from about 200° C. to about 400° C. This temperature is maintained throughout the process.

Generally, prior to the first pulse in the pulse cycle, the reaction chamber is also brought to a pressure of about 0.1 to 5 Torr, and preferably about 0.1 to 2 Torr. This pressure is also maintained throughout the process.

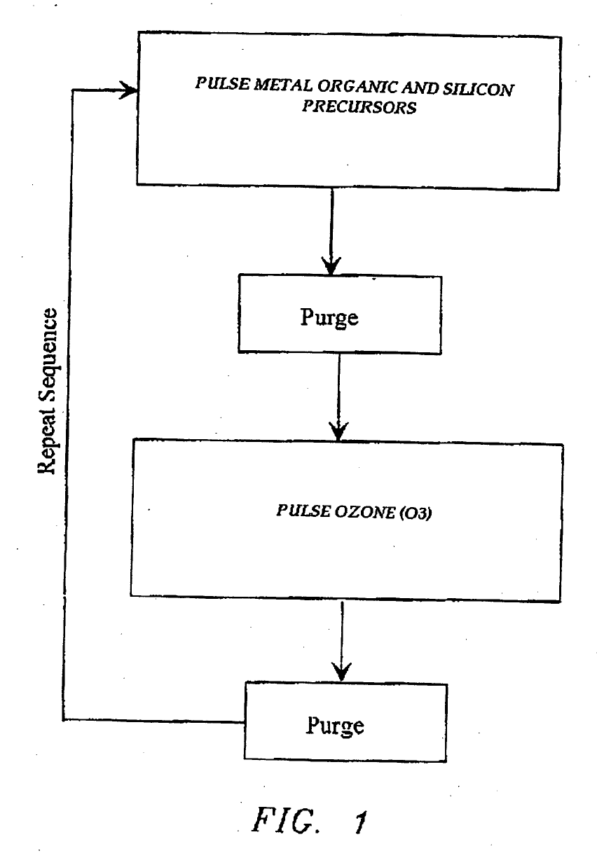

The pulse cycle is visually illustrated in FIG. 1. The pulse cycle comprises the following steps:

First, a volatile liquid metal organic precursor and volatile liquid silicon precursor are volatilized and pulsed either jointly or independently, and either concurrently or consecutively, into a reaction chamber. The metal organic precursor and silicon source are then chemi-absorbed and/or physi-absorbed onto the surface of the substrate.

In general, both the metal organic precursor and the silicon precursor are introduced over a period ranging from about 0.1 to about 5 seconds at a flow rate ranging from about 0.1 to about 1100 standard cubic centimeters per minute (“sccm”). The precursors, or precursor mixture, can be introduced in combination with an inert carrier gas, such as argon, nitrogen or helium gas. Alternatively, the precursors, or precursor mixture, can be introduced in pure form. Preferably, the precursor liquids are mixed and then volatilized and then introduced into the reaction chamber in conjunction with argon gas.

The metal organic precursor can be any metal donating organic material. Preferred metal organic precursors include metal alkyls, metal alkoxides and metal alkyl amides. Preferably, however, the metal organic precursor is a metal alkyl amide. The metal alkyl amides tend to incorporate less carbon contamination in the resultant film.

Suitable metal alkyl amides conform to the following formula:
M(NR¹R²)ₙ
wherein “M” is a metal, “R¹” and “R²,” independently, are selected from the group comprising substituted or unsubstituted linear, branched, and cyclic alkyls, and “n” is a number corresponding to the valence of the metal. Preferably, “M” is a Group 4 (Ti, Zr, Hf) metal (Group 4 being the new periodic table notation which corresponds to Group IVA in the previous IUPAC form and Group IVB in the CAS version). Ideally, the metal is hafnium. Preferably, “R¹” and “R²” are, individually, a C₁-C₆ alkyl, such as methyl and ethyl, since these ligands reduce carbon contamination in the resultant film. Even more preferably, “R¹” and “R²” are ethyl and methyl units, respectively. The use of metal alkyl amides with ethylmethyl amide ligands generates less carbon contamination in the metal silicate film. For example, Hf-TEMA generates less carbon contamination than related compounds, such as Hf-TDMA and hafnium tetraethyl amide (“Hf-TDEA”).

The silicon organic precursor can be any silicon donating organic material. Preferred silicon organic precursors include alkyl silanes, silicon alkoxides, siloxanes, silazanes, and silicon alkyl amides. For example, suitable silicon organic precursors include alkyl silanes such as tetramethyl silane, silicon alkoxides such as silicon-tetrakis-t-butoxide, siloxanes such as hexamethyldisiloxane (“HMDSO”) and tetramethyldisiloxane (“TMDSO”), and silazanes such as hexamethyldisilazene. Preferably, however, the silicon organic precursor is a silicon alkyl amide. The silicon alkyl amides generate less carbon content in the resultant metal silicate film.

Suitable silicon alkyl amides include compounds conforming to the following formula:
Si(NR¹R²)₄
wherein “R¹” and “R²,” independently, are selected from the group comprising substituted or unsubstituted linear, branched, and cyclic alkyls. Preferably, “R¹” and “R²” are, individually, a C₁-C₆ alkyl, such as methyl and ethyl. Even more preferably, the silicon alkyl amide is silicon tetrakis (ethylmethyl amide) (“Si-TEMA”) as this compound generates less carbon contamination in the metal silicate film, even when compared to similar compounds such as silicon tetraks (diethyl amide) (“Si-TDEA”) and silicon tetrakis (dimethyl amide) (“Si-TDMA”).

Second, the reaction chamber is purged of unreacted metal organic precursor, unreacted silicon organic precursor, and by-product. The purge may be conducted using, for example, an inactive purge gas or a vacuum purge. Inactive purge gases include argon, nitrogen and helium gas. The purge gas is generally pulsed into the reaction chamber over a period ranging from about 0.1 to about 5 seconds at a flow rate ranging from about 0.1 to about 1100 sccm.

Third, ozone gas is pulsed into the reaction chamber. The ozone is generally pulsed into the reaction chamber over a period ranging from about 0.1 to about 5 seconds at a flow rate ranging from about 0.1 to about 1100 sccm. The ozone can be introduced with an inert gas, such as argon, nitrogen or helium gas. Alternatively, the ozone can be added in pure form. By “pure” it is not meant that oxygen gas is completely absent. Oxygen gas is the precursor to ozone and is almost always present in ozone to some degree. Ozone severs the ligands on the metal organic precursor and silicon organic precursor and adds the necessary oxygen to form metal silicate.

By using ozone in the ALD process, as opposed to conventional oxidants such as oxygen gas and steam, the fixed and trapped charges in the resultant metal silicate are reduced. In addition, the required operating temperatures are reduced. Traditionally, oxygen gas and steam have been preferred oxidants in ALD processes, whereas ozone has been recognized as an oxidant but disfavored due to its relatively high instability. However, it has been discovered that ozone is actually the preferred oxidant in the formation of metal silicate films by ALD. Whereas oxygen gas requires operating temperatures around 400° C., ozone permits operating temperatures below 300° C. Whereas steam causes hydroxyl contamination in the resultant film, ozone produces films free of such contamination.

Fourth, and finally, the reaction chamber is purged of unreacted ozone and by-product. This second purging step is generally conducted in the same manner as the first purging step.

This completes one cycle of the ALD process. The end result is the formation of one mono-layer of metal silicate on the substrate. The pulse cycle is then repeated as many times as necessary to obtain the desired film thickness. The layer by layer ALD growth provides excellent coverage over large substrate areas and provides excellent step coverage.

Preferred metal silicates formed in accordance with the invention are Group 4 metal silicates such as hafnium silicate, zirconium silicate, and titanium silicate. The most preferred metal silicate is hafnium silicate. Hafnium silicate exhibits superior thermal stability and, thereby, results in less interfacial silicon dioxide growth.

A hafnium silicate (HfₓSi₁₋ₓO₂) film can be formed on a silicon substrate by pulsing a vapor mixture of Hf-TEMA and Si-TEMA in a 1:4 ratio, followed by a purge, followed by pulsing ozone, followed by a second purge. Preferably, the pressure is 0.5 Torr throughout the process and the vaporizer set point is 125° C. and the line heaters are at 135° C.

An illustrative pulse cycle would be as follows: first, precursors are pulsed into the chamber at concentration of 0.04 g/min and a flow rate of 300 sccm for 2 seconds; second, argon purge is pulsed into the chamber at a flow rate of 300 sccm for 3 seconds; third, ozone is pulsed into the chamber at a flow rate of 300 sccm for 2 seconds; fourth, and finally, argon is pulsed into the chamber at a flow rate of 300 sccm for 3 seconds. These conditions give a uniformity of approximately 1.5% (1 σ) and a deposition rate of approximately 0.95 Å/cycle.

In general, increases in wafer temperature increase the deposition rate and the equivalent thickness (Tox) and decrease the leakage current density (Jg). Increases in ozone pulse time increase deposition rate and Tox and decrease Jg. In addition, it was determined that the percentages of hafnium and silicon in the resultant film are tied to wafer temperature. Specifically, the percentage of hafnium decreases and the percentage of silicon increases as the wafer temperature rises. In fact, the percentage of silicon nearly doubles as wafer temperature rises from 300° C. to 400° C., but then plateaus and does not show much increase to 450° C. For example, at a wafer temperature of 350° C., the atomic percentages in the film were 1.4% hydrogen, 3.0% carbon, 63.4% oxygen, 10.9% silicon, 20.3% hafnium, and 1.0% nitrogen. In contrast, at a wafer temperature of 400° C., the atomic percentages in the film were 1.8% hydrogen, 2.5% carbon, 62.7% oxygen, 13.3% silicon, 18.5% hafnium, and 1.2% nitrogen. However, at a wafer temperature of 450° C., the atomic percentages in the film were 1.0% hydrogen, 2.1% carbon, 63.8% oxygen, 13.7% silicon, 18.8% hafnium, and 0.6% nitrogen.

The ALD process of the instant invention can be used to create high k dielectrics for use in gate and capacitor structures. For example, the process can be used to create gates by forming a high k metal silicate film on a substrate, such as a doped silicon wafer, and capping the structure with a conductive layer, such as doped Poly Si. Alternatively, the process can be used to create capacitors by forming a high k metal silicate film between two conductive plates.

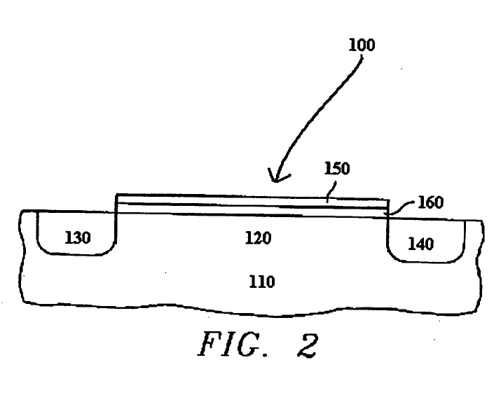

FIG. 2 is illustrative of the use of such high k dielectrics in a gate. In FIG. 2, a field effect transistor 100 is shown in cross section. The transistor includes a lightly p-doped silicon substrate 110 in which a n-doped silicon source 130 and a n-doped silicon drain 140 have been formed leaving a channel region 120 there between. A gate dielectric 160 is positioned over channel region 120. A gate electrode 150 is positioned over the gate dielectric 160, so that it is only separated from channel region 120 by the intermediate gate dielectric 160. When a voltage difference exists between source 130 and drain 140, no current flows through channel region 120, since one junction at the source 130 or drain 140 is back biased. However, by applying a positive voltage to gate electrode 150, current flows through channel region 120. The gate dielectric 160 is a high k metal silicate made in accordance with the ALD process of the invention.

It will be apparent to the skilled artisan that many variations of the instant invention are possible. For example, ozone can be generated and delivered in a number of ways. In addition, the particulars of ALD chambers, gas distribution devices, valves, timing, and the like, often vary. Other variations within the spirit and scope of this invention may exist that have not necessarily been detailed herein. Accordingly, the invention is only limited by the scope of the claims that follow.

What is claimed is:

1. A method of growing a metal silicate film on a substrate by atomic layer deposition comprising:
(i) introducing a metal organic precursor and a silicon organic precursor into a reaction chamber containing a substrate;
(ii) purging the reaction chamber;
(iii) introducing ozone into the reaction chamber;
(iv) purging the reaction chamber; and
(v) repeating steps (i), (ii), (iii) and (iv) until a film of a target thickness is achieved on the substrate.

2. The method of claim 1, wherein the substrate is silicon.

3. The method of claim 1, wherein the metal in the metal organic precursor is a Group 4 metal.

4. The method of claim 1, wherein the metal in the metal organic precursor is hafnium.

5. The method of claim 1, wherein the metal organic precursor is a linear, branched and cyclic alkyl.

6. The method of claim 1, wherein the metal organic precursor is a metal alkyl amide.

7. The method of claim 1, wherein the silicon organic precursor is a silicon alkyl amide.

8. The method of claim 1, wherein the metal organic precursor is a metal alkoxide.

9. The method of claim 1, wherein the metal organic precursor and the silicon organic precursor are mixed, volatilized, and introduced into the chamber as a mixed gas.

10. The method of claim 1, wherein the metal organic precursor and the silicon organic precursor are volatilized separately and introduced into the chamber concurrently.

11. The method of claim 1, wherein the metal organic precursor and the silicon organic precursor are volatilized separately and introduced into the chamber consecutively.

12. A method of forming a gate for a transistor comprising:
(i) introducing a metal organic precursor and a silicon organic precursor into a reaction chamber containing a substrate;
(ii) purging the reaction chamber;
(iii) introducing ozone into the reaction chamber;
(iv) purging the reaction chamber;
(v) repeating steps (i), (ii), (iii) and (iv) until a dielectric film of a target thickness is achieved on the substrate; and
(vi) placing a conductive film over the dielectric film.

13. The method of claim 12, wherein the substrate is silicon.

14. The method of claim 12, wherein the metal organic precursor is a linear, branched, and cyclic amide of Group 4 metal and wherein the silicon organic precursor is a silicon donating organic material.

15. The method of claim 12, wherein the metal organic precursor is a metal alkyl amide of a Group 4 metal, and wherein the silicon organic precursor is a silicon alkyl amide.

16. The method of claim 12, wherein the metal organic precursor and the silicon organic precursor are mixed, volatilized, and introduced into the chamber as a mixed gas.

17. The method of claim 12, wherein the metal organic precursor and the silicon organic precursor are volatilized separately and introduced into the chamber concurrently.

18. The method of claim 12, wherein the metal organic precursor and the silicon organic precursor are volatilized separately and introduced into the chamber consecutively.

19. A method of forming a capacitor comprising:
(i) introducing a metal organic precursor and a silicon organic precursor into a reaction chamber containing a substrate;
(ii) purging the reaction chamber;
(iii) introducing ozone into the reaction chamber;
(iv) purging the reaction chamber;
(v) repeating steps (i), (ii), (iii) and (iv) until a dielectric film of a target thickness is achieved on the substrate; and
(vi) positioning the film between two electrodes.

20. The method of claim 19, wherein the substrate is one of the two electrodes.

21. The method of claim 19, wherein the metal organic precursor is a linear, branched and cyclic amide of Group 4 metal and wherein the silicon organic precursor is a silicon donating organic material.

22. The method of claim 19, wherein the metal organic precursor is a metal alkyl amide of a Group 4 metal, and wherein the silicon organic precursor is a silicon alkyl amide.

23. The method of claim 19, wherein the metal organic precursor and the silicon organic precursor are mixed, volatilized, and introduced into the chamber as a mixed gas.

24. The method of claim 19, wherein the metal organic precursor and the silicon organic precursor are volatilized separately and introduced into the chamber concurrently.

25. The method of claim 19, wherein the metal organic precursor and the silicon organic precursor are volatilized separately and introduced into the chamber consecutively.
